(19) United States
(12) Patent Application Publication
(10) Pub. No.: US 2026/0261797 A1
(43) Pub. Date: Sep. 3, 2026

(54) FORCE CONTROLLED LOUDSPEAKER PROTECTION SYSTEM

(71) Applicant: Dolby Laboratories Licensing Corporation, San Francisco, CA (US)

(72) Inventor: Ho Young SUNG, Meadowbank, NSW (AU)

(73) Assignee: Dolby Laboratories Licensing Corporation, San Francisco, CA (US)

(21) Appl. No.: 19/159,997

(22) PCT Filed: Feb. 22, 2024
(86) PCT No.: PCT/US2024/016861

§ 371 Date: Aug. 26, 2025

Related U.S. Application Data
(60) Provisional application No. 63/487,062, filed on Feb. 27, 2023.

(30) Foreign Application Priority Data
Feb. 27, 2023 (EP) 23158673.6

(51) Int. Cl. H04R 3/00; H03F 1/52

(52) U.S. Cl. CPC H04R 3/002; H03F 1/52; H04R 3/007; H03F 2200/03; H03F 2200/462; H03F 2200/471

(57) ABSTRACT

Systems and methods for force-controlled protection of a loudspeaker. One system includes a driver, an audio source that outputs an audio signal for playback by the driver, a power amplifier that provides power to the driver for playing back the audio signal, and a controller including an electronic processor. The controller is configured to receive the audio signal from the audio source, predict an amount of force exerted by the driver based on a voltage level of the audio signal, determine whether the predicted amount of force exceeds a threshold, and limit an amount of voltage provided to the power amplifier when the predicted amount of force exceeds the threshold.

### CROSS-REFERENCE TO RELATED APPLICATIONS

The present disclosure claims the benefit of priority from U.S. Provisional Patent Application No. 63/487,062 filed on 27 Feb. 2023 and European Patent Application No. 23158673.6 filed on 27 Feb. 2023, each of which is incorporated by reference herein in its entirety.

### FIELD OF THE DISCLOSURE

This application relates generally to systems and methods of protecting loudspeakers.

### BRIEF SUMMARY OF THE DISCLOSURE

Loudspeakers may experience mechanical failure, such as a blow out, when too much electrical power is applied to the driver and/or when physical damage to one or more driver components, such as the voice coil or the diaphragm, occurs after repeated use. In an attempt to prevent mechanical failure of the loudspeaker, some existing loudspeaker systems implement excursion-based control methods that limit the driver from experiencing excessive excursion during playback of an audio signal. However, there is limited evidence to support that excessive excursion of a loudspeaker driver results in mechanical failure. Moreover, the existing excursion-based systems and methods for protecting loudspeakers from mechanical failure are generally ineffective. Accordingly, improved systems and methods for protecting loudspeakers from mechanical failure are desired.

Various aspects of the present disclosure relate to devices, systems, and methods for force-controlled protection of loudspeakers. For example, in some aspects, the disclosure provides a controller that predicts an amount of force exerted by a speaker driver during playback of an audio signal. When the predicted amount of force exceeds a force threshold associated with mechanical failure of the loudspeaker, the controller limits an amount of power supplied from the power amplifier to the speaker driver.

In one example aspect of the present disclosure, there is provided a force-controlled loudspeaker protection system that includes a driver, an audio source that outputs an audio signal for playback by the driver, a power amplifier that provides power to the driver for playing back the audio signal, and a controller including an electronic processor. The controller is configured to receive the audio signal from the audio source, predict an amount of force exerted by the driver based on a voltage level of the audio signal, determine whether the predicted amount of force exceeds a threshold, and limit an amount of voltage provided to the power amplifier when the predicted amount of force exceeds the threshold.

In another example aspect of the present disclosure, there is provided a method for force-controlled protection of a loudspeaker. The method includes receiving, from an audio source, an audio signal for playback by a loudspeaker driver, predicting, by a controller including an electronic processor, an amount of force exerted by the driver based on a voltage of the audio signal, determining, by the controller, whether the predicted amount of forces exceeds a force threshold, and limiting, by the controller, an amount of voltage provided to a power amplifier when the predicted amount of force exceeds the force threshold.

In another example aspect of the present disclosure, there is provided a non-transitory computer-readable medium storing instructions that, when executed by a processor of force-controlled loudspeaker protection system delivery system, cause the force-controlled speaker protection system to perform operations comprising receiving, from an audio source, an audio signal for playback by a loudspeaker driver, predicting, by a controller including an electronic processor, an amount of force exerted by the driver based on a voltage of the audio signal, determining, by the controller, whether the predicted amount of forces exceeds a force threshold, and limiting, by the controller, an amount of voltage provided to a power amplifier when the predicted amount of force exceeds the force threshold.

In this manner, various aspects of the present disclosure provide for the force-controlled protection of a loudspeaker and the like.

### DESCRIPTION OF THE DRAWINGS

These and other more detailed and specific features of various embodiments are more fully disclosed in the following description, reference being had to the accompanying drawings, in which:

FIG. 1 depicts an example block diagram of a force-controlled protection system for a loudspeaker.

FIG. 2A depicts an example electrical equivalent circuit for a loudspeaker.

FIG. 2B depicts an example mechanical equivalent circuit for a loudspeaker.

FIG. 2C depicts an example acoustical equivalent circuit for a loudspeaker.

FIG. 2D depicts an example combined equivalent circuit for a loudspeaker.

FIG. 3 is a flowchart that depicts an example method for force-controlled protection of a loudspeaker.

FIGS. 4A-4C depict an example block diagram of a force-controlled protection system for a loudspeaker.

FIG. 5 is a flowchart that depicts an example method for force-controlled protection of a loudspeaker.

FIG. 6A is an example graph that depicts predicted and measured amounts of force exerted by a loudspeaker.

FIG. 6B is an example graph that depicts predicted and measured amounts of excursion experienced by a loudspeaker.

FIG. 7A is an example graph that depicts predicted and measured amounts of force exerted by a loudspeaker.

FIG. 7B is an example graph that depicts predicted and measured amounts of excursion experienced by a loudspeaker.

### DETAILED DESCRIPTION

This disclosure and aspects thereof can be embodied in various forms, including hardware, devices or circuits controlled by computer-implemented methods, computer program products, computer systems and networks, user interfaces, and application programming interfaces; as well as hardware-implemented methods, signal processing circuits, memory arrays, application specific integrated circuits (ASICs), field programmable gate arrays (FPGAs), and the like. The foregoing is intended solely to give a general idea of various aspects of the present disclosure, and does not limit the scope of the disclosure in any way.

In the following description, numerous details are set forth, such as audio device configurations, timings, operations, and the like, in order to provide an understanding of one or more aspects of the present disclosure. It will be readily apparent to one skilled in the art that these specific details are merely examples and not intended to limit the scope of this application.

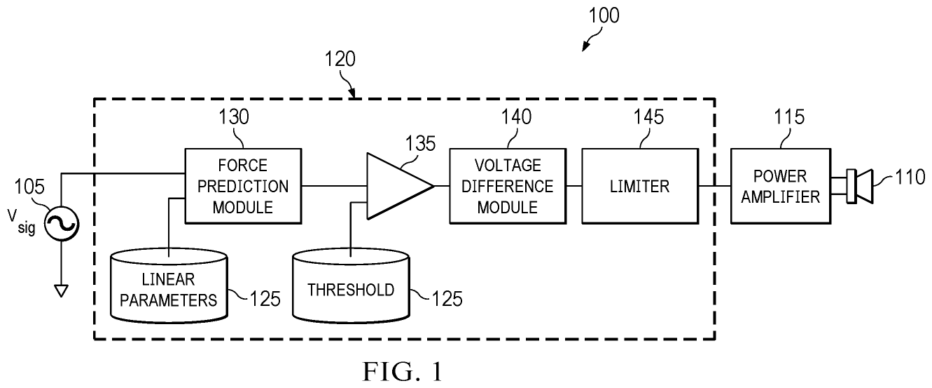

FIG. 1 depicts an example block diagram of a force-controlled protection system 100 for a loudspeaker. The system 100 includes, among other things, an audio source 105, a speaker driver 110, a power amplifier 115, and a controller 120. The audio source 105 provides an audio signal having a voltage V_{sig} that is to be played back by the driver 110. The audio source 105 may be, for example, one or more of a television, a laptop computer, a desktop computer, a smartphone, a compact disc player, or any other device capable of producing and/or transmitting an audio signal and/or other media content that includes audio. In some instances, the audio source 105 provides the audio signal to the controller 120 using a wired connection. In other instances, the audio source 105 provides the audio signal to the controller 120 using a wireless connection.

The driver 110 may be, for example, a full-range driver, a subwoofer, a woofer, a mid-range driver, a tweeter, or some other type of speaker driver. Although not explicitly illustrated, it should be understood that the driver 110 includes one or more standard components that are included in commonly used speaker drivers. For example, the driver 110 may include, among other things, a voice coil and a diaphragm that converts mechanical vibrations to sound. Although shown as a single driver 110 in the illustrated example of FIG. 1, it should be understood that in some instances, the system 100 includes one or more drivers 110.

The power amplifier 115 is configured to amplify the relatively low-power audio signal input by the audio source 105 to a level that is high enough for playback by the driver 110. For example, the power amplifier 115 is configured to increase one or more of the voltage, current, and/or power of the of the audio signal provided by the audio source 105. In the illustrated example of FIG. 1, the system 100 includes a power amplifier 115 that does not provide current and/or voltage feedback to the controller 120. However, as will be described in more detail below, in some instances, the force-controlled loudspeaker protection systems include smart power amplifiers that provide current and/or voltage feedback to the system controller. In some instances, the power amplifier 115 is implemented as a current-controlled power amplifier, such as a transconductance power amplifier. When compared to commonly used voltage-controlled power amplifiers, which amplify the input voltage of an audio signal to an output voltage, a current-controlled power amplifier amplifies the input current of an audio signal to an output current.

As will be described in more detail below, the controller 120 is configured to control an amount force exerted by the driver 110. For example, the controller 120 is configured to predict, or determine, an amount of force exerted by the driver 110 based on the input voltage V_{sig} of the audio signal and control an amount of power provided by power amplifier 115 to the driver 110 accordingly. In the illustrated example, the controller 120 is implemented as microchip device that includes a plurality of electrical and electronic components for providing power, operational control, and protection to the components and modules within the controller 120 and/or the force-controlled protection system 100. For example, the controller 120 includes, among other things, a memory 125 and a plurality electronic processor modules. The plurality of electronic processor modules includes a force prediction module 130, a comparator 135, a voltage difference module 140, and a limiter 145. Although illustrated as separate modules within the controller 120, it should be understood that in some embodiments, the respective functionalities of the plurality of electronic processor modules may be performed by a single processor module or a single electronic processor included in the controller 120.

The memory 125 includes, for example, a program storage area and a data storage area. The program storage area and the data storage area may include combinations of different types of memory, such as read-only memory (ROM) and/or random-access memory (RAM). Various non-transitory computer readable media, for example, magnetic, optical, physical, or electronic memory may be used. The electronic processor modules are communicatively coupled to the memory 125 and execute software instructions that are stored in the memory 125, or stored on another non-transitory computer readable medium such as another memory or a disc. Instructions may include instructions, which when executed by the electronic processor modules, control operation of the power amplifier 115 and/or the driver 110 as described herein. The software may include one or more applications, program data, filters, rules, one or more program modules, and other executable instructions.

Furthermore, as shown in the illustrated example of FIG. 1, the memory 125 stores one or more linear parameters, also known as the Thiele-Small parameters, of the driver 110. For example, the memory 125 stores one or more of the direct-current (DC) resistance R_{E} of the driver 110, the electrical inductance L_{E} of the driver 110, the resonance frequency F_{S} of the driver 110, the mechanical mass M_{MS} of the diaphragm of the driver 110 (e.g., with air loading), the mechanical resistance R_{ES} of the driver 110, the mechanical resistance R_{MS} of the suspension of driver 110, the mechanical compliance C_{MS} of the suspension of driver 110, the volume compliance V_{AS} of the suspension of driver 110 the effective piston area S_{D} of the driver 110, the mechanical quality factor Q_{MS} of the driver 110, the electrical quality factor Q_{ES} of the driver 110, the total quality factor Q_{TS} of the driver 110, and the force factor Bl of the driver 110. In some instances, the memory 125 stores one or more additional parameters of the driver 110 that are not explicitly described herein. In some instances, values of the linear parameters are measured before storage in the memory. In other instances, values of the linear parameters are provided by a manufacturer of the driver 110.

As further shown in FIG. 1, the memory 125 also stores one or more thresholds for the force exerted by the driver 110. For example, the memory 125 stores a force threshold that is used by controller 120 to limit the output power of the power amplifier 115. The force threshold is indicative of an amount of force exerted by the driver 110 that may result in mechanical failure of the driver 110. For example, the driver 110 may experience mechanical failure after exerting a force that exceeds the force threshold one or more times.

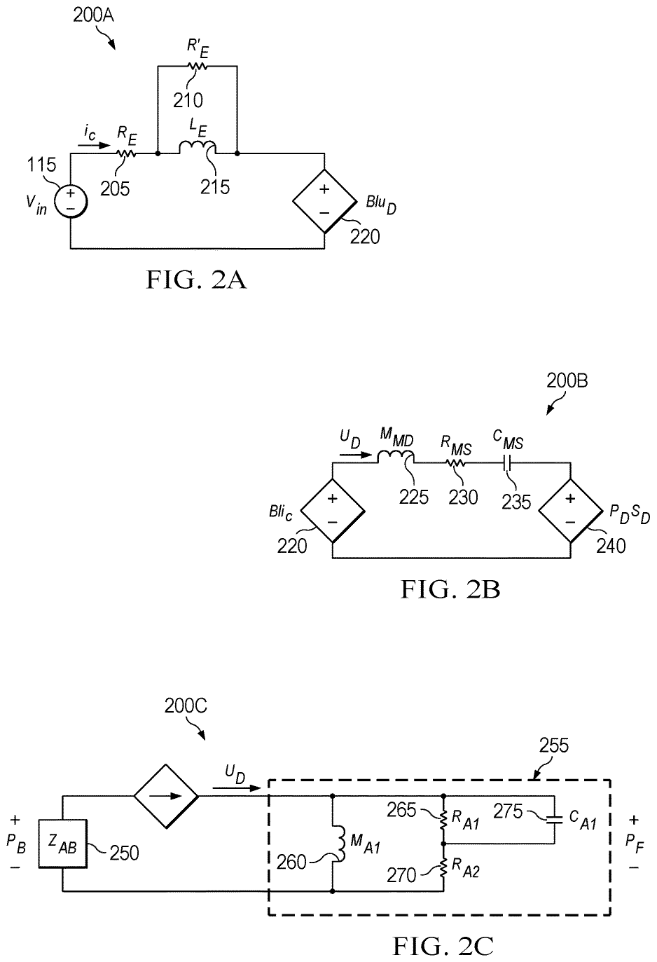

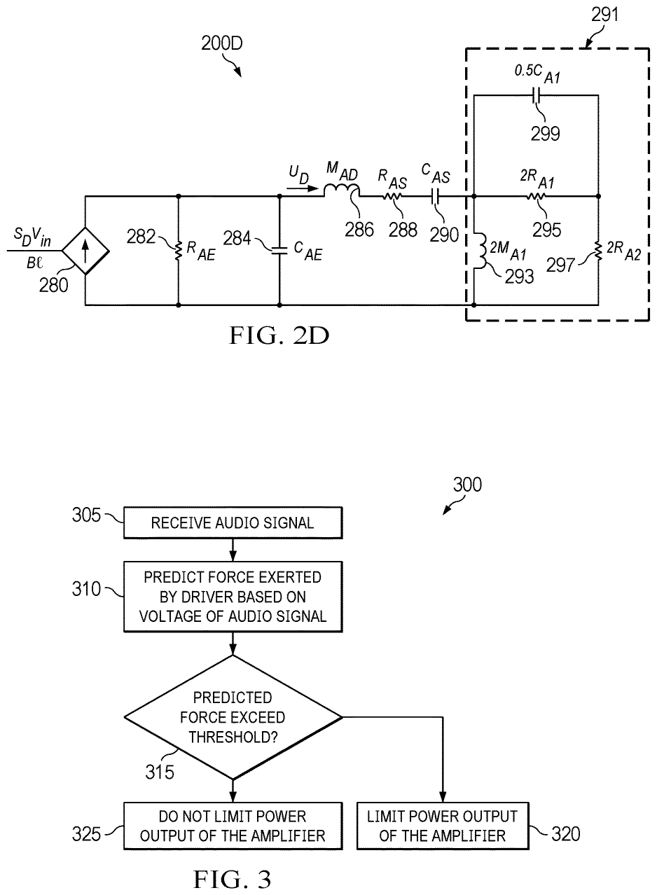

In operation, the force prediction module 130 predicts, or estimates, an amount of force exerted by the driver 110 based on the voltage V_{sig} of the audio signal received form the audio source 105. In one example, the force prediction module 130 uses Equation 1 to predict the amount of force F exerted by the driver 110. In other examples, the force prediction module 130 uses different equations and/or methods for predicting the amount of force exerted by the driver 110. As will be described in more detail below with respect to FIGS. 2A-2C, Equation 1 is expressed in terms of the above-described linear parameters of the driver 110 and may be derived from one or more analogous circuit models of the driver 110.

$$F = {M}_{MS} a + {R}_{MS} {u}_{D} + \frac{1}{{c}_{MS}} {x}_{D} \qquad [ Equation 1 ]$$

Equation 1 expresses the force F exerted by the driver 110 as a function of the diaphragm velocity u_{D} of the driver 110. As expressed below by Equations 2 and 3 respectively, the diaphragm acceleration a is a derivative of the diaphragm velocity u_{D} of the driver 110 and the diaphragm excursion x_{D} is an integral of the diaphragm velocity u_{D} of the driver 110.

$$a = \frac{{du}_{D}}{dt} \qquad [ Equation 2 ]$$

$${x}_{D} = \int {u}_{D} dt \qquad [ Equation 3 ]$$

As will be described below with respect to the analogous circuit models of the driver 110 shown in FIGS. 2A-2C, the diaphragm velocity u_{D} of the driver 110 can be expressed in terms of the linear parameters of the driver 110 using Equations 4-9 below.

$${u}_{D} = \frac{{R}_{AE}}{Bl \cdot {R}_{AT}} \frac{\frac{{ω}_{0} {ω}_{u 1}}{{Q}_{TS}} {s}^{2}}{( {s}^{2} + \frac{{ω}_{0}}{{Q}_{TS}} s + {ω}_{0}^{2} ) ( s + {ω}_{u 1} )} {v}_{amp} \qquad [ Equation 4 ]$$

$${R}_{AE} = \frac{{Bl}^{2}}{{s}_{D}^{2} \cdot {R}_{E}} \qquad [ Equation 5 ]$$

$${R}_{AT} = {R}_{AE} + \frac{{R}_{MS}}{{S}_{D}^{2}} \qquad [ Equation 6 ]$$

$${ω}_{s} = 2 π {F}_{s} \qquad [ Equation 7 ]$$

$${ω}_{u 1} = 2 π {f}_{u 1} = \frac{{R}_{E} {M}_{Ms}}{{L}_{E} {M}_{MD}} \qquad [ Equation 8 ]$$

$${M}_{MD} = {M}_{MS} - \frac{2 {S}_{D}^{2} 8 {ρ}_{0}}{3 {π}^{2} \sqrt{{S}_{D} / π}} \qquad [ Equation 9 ]$$

With respect to Equation 4 above, vₐₘₚ is the output voltage of the power amplifier 115, which is fed to the input terminals of the driver 110. With respect to Equations 8 and 9 above, the mechanical mass of the diaphragm M_{MD} without air loading is a function of the air density ρ₀ and the effective piston area S_{D} of the driver 110.

In operation, the driver 110 converts an electrical signal (e.g., signal having a voltage vₐₘₚ received from the power amplifier 115) into mechanical movement, for example, by setting a voice coil of the driver 110 into motion. The diaphragm of the driver 110 moves along with the coil and creates differences in air pressure. This mechanical movement and resultant differences in air pressure are then converted into acoustical output, or sound, that is produced by the driver 110. As described above, by using the linear parameters of the driver 110, the driver 110 can be modeled by one or more analogous circuits that behave, or operate, in an electrically similar manner to that of the driver 110. FIGS. 2A-2C respectively illustrate an electrical equivalent circuit 200A of the driver 110, a mechanical equivalent circuit 200B of the driver 110, and an acoustical equivalent circuit 200C of the driver 110 that can be used to model operation of the driver 110.

As shown in FIG. 2A, the electrical equivalent circuit 200A includes the power amplifier 115, which is modeled as a voltage source that outputs a voltage vₐₘₚ to the input terminals of the driver 110. The electrical equivalent circuit 200A further includes a first resistor 205, which has a resistance R_{E}, that models the DC resistance of the coil included in the driver 110 and a second resistor 210, which has a resistance R′_{E}. The resistance R′_{E}. is indicative of the magnetic loss caused by eddy currents flowing through the magnetic circuit. An inductor 215, which has an inductance L_{E}, that models the DC inductance of the coil included in the driver 110 is connected in parallel with the second resistor 210. As will be described in more detail below with respect to FIG. 2B, the electrical equivalent circuit 200A further includes the primary side of an electro-mechanical transformer 220. The voltage at the primary side of the electro-mechanical transformer 220 is Blu_{D}. A coil current i_{c} flows through the electrical equivalent circuit 200A.

When comparing an electrical system to a translational mechanical system, voltage is analogous to force and current is analogous to velocity. Moreover, a given power in Watts can result from the product of a voltage and a current or the product of a force and a velocity. Accordingly, the mechanical equivalent circuit 200B shown in FIG. 2B can be used to model the mechanical impedance of the driver 110. The mechanical equivalent circuit 200B includes the secondary side of the electro-mechanical transformer 220, which applies a force equivalent voltage of Bli_{c} to the input side of the mechanical equivalent circuit 200B. The mechanical equivalent circuit 200B further includes a second inductor 225, which has an inductance M_{MD}, that models the mechanical mass of the diaphragm of the driver 110, a third resistor 230, which as a resistance R_{MS}, that models the mechanical resistance of the suspension of driver 110, and a capacitor 235, which has a capacitance C_{MS}, that models the mechanical compliance of the suspension of driver 110. A pressure equivalent current of up flows through the mechanical equivalent circuit 200B. As will be described in more detail below with respect to FIG. 2C, the mechanical equivalent circuit 200B further includes the primary side of a mechanical-acoustical transformer 240. The force equivalent voltage at the primary side of the mechanical-acoustical transformer 240 is P_{D}S_{D}.

When comparing a translational mechanical system to an acoustical system, force is analogous to pressure and velocity is analogous to volumetric flow rate. Moreover, a given power can result from the product of a force and a velocity or a pressure and a volumetric flow rate, or volume velocity. Accordingly, the acoustical equivalent circuit 200C shown in FIG. 2C can be used to model the acoustical impedance of the driver 110. The equivalent impedance of the electrical and mechanical equivalent circuits 200A, 200B is modeled as a component 250, which has an impedance Z_{AB}, connected at the input side of the acoustical equivalent circuit 200C (e.g., the secondary side of the mechanical-acoustical transformer 240). The impedance Z_{AB} is indicative of the acoustic impedance of a backside of the diaphragm included in the driver 110. The pressure difference across the component 250 (e.g., pressure difference across the backside of the diaphragm included in the driver 110) is P_{D} and the volume velocity flowing through the acoustical equivalent circuit 200C is U_{D}, where U_{D} is expressed below in Equation 10 as the product of the diaphragm velocity u_{D} and the effective piston area S_{D} of the driver 110.

$${U}_{D} = {u}_{D} {S}_{D} \qquad [ Equation 10 ]$$

The output side of the acoustical equivalent circuit 200C has an acoustic impedance component 255, which has an impedance Z_{AF}. The impedance Z_{AF} is indicative of the acoustic impedance of the frontside of the diaphragm included in the driver 110. The pressure difference across the acoustic impedance component 255 (e.g., pressure difference across the frontside of the diaphragm included in the driver 110) is P_{F}. As shown, the acoustic impedance component 255 comprises an inductive component 260 which has an inductance M_{A1}, a first resistive component 265 which has an resistance R_{A1}, a second resistive component 270 which has an resistance R_{A2}, and a capacitive component 275 which has an capacitance C_{A1}. Using Equations 11-14 below, the inductance M_{A1}, the resistance R_{A1}, the resistance R_{A2}, and the capacitance C_{A1} are expressed in terms of the piston radius a, the air density po, and the speed of sound c.

$${M}_{A 1} = \frac{8 {ρ}_{0}}{3 π {a}^{2}} \qquad [ Equation 11 ]$$

$${R}_{A 1} = \frac{0.441 {ρ}_{0} c}{π {a}^{2}} \qquad [ Equation 12 ]$$

$${R}_{A 2} = \frac{c}{π {a}^{2}} \qquad [ Equation 13 ]$$

$${C}_{A 1} = \frac{5.94 {a}^{3}}{{ρ}_{0} {c}^{2}} \qquad [ Equation 14 ]$$

Using known circuit analysis techniques, the equivalent circuits 200A-200C shown in FIGS. 2A-2C can be combined into a single equivalent circuit model of the driver 110, the equivalent circuit 200D. FIG. 2D illustrates the equivalent circuit 200D. The equivalent circuit 200D is an equivalent model of the acoustic impedance of the back and front sides of the driver 110 with air loading. The equivalent circuit 200D includes various circuit components that are defined in terms of the linear parameters of the driver 110 described herein.

For example, the equivalent circuit 200D includes a source 280 having a pressure difference of

$$\frac{{SS}_{D} {V}_{in}}{Bl} ,$$

a first resistive component 282 having a resistance R_{AE}, a first capacitive component 284 having a capacitance C_{AE}, an inductive component 286 having an inductance M_{AD}, a second resistive component 288 having a resistance R_{AS}, and a second capacitive component 290 having a capacitance C_{AS}. The resistance R_{AE} is expressed in terms of the linear parameters of the driver 110 above by Equation 5. The capacitance C_{AE}, the inductance M_{AD}, the resistance R_{AS}, the capacitance C_{AS} are respectively expressed in terms of the linear parameters of the driver 110 below by Equations 15-18.

$${C}_{AE} = \frac{{S}_{D}^{2} {L}_{E}}{{( Bl )}^{2}} \qquad [ Equation 15 ]$$

$${M}_{AD} = \frac{{M}_{MD}}{{s}_{D}^{2}} \qquad [ Equation 16 ]$$

$${R}_{AS} = \frac{{R}_{MS}}{{s}_{D}^{2}} \qquad [ Equation 17 ]$$

$${C}_{AS} = {S}_{D}^{2} {C}_{MS} \qquad [ Equation 18 ]$$

The equivalent circuit 200D further includes an output impedance component 291 having an impedance that is equal to the sum of impedances Z_{AB} and Z_{AF}. As shown in FIG. 2D, the output impedance component 291 includes an inductive component 293 which has an inductance 2M_{A1}, a first resistive component 295 which has a first resistance 2R_{A1}, a second resistive component 297 which has an resistance 2R_{A2}, and a capacitive component 299 which has an capacitance 0.5C_{A1}.

By using known circuit analysis techniques to solve the equivalent circuits 200A-200D, the above-described Equation 1 can be derived and used to determine the amount of force exerted by the driver 110. As described above, in some instances, the force prediction module 130 uses Equation 1 to predict the amount of force exerted by the driver 110. In other instances, the force prediction module 130 uses one or more additional and/or different equations and/or methods to predict the amount of force exerted by the driver.

With reference to FIG. 1, the force prediction module 130 outputs the predicted amount of force exerted by the driver 110 to the comparator 135. The comparator 135 compares the predicted amount of force to a force threshold stored in the memory 125. For example, the comparator 135 determines a difference between the predicted amount of force and a force threshold stored in memory 125. The comparator 135 outputs the difference between the predicted amount of force and the force threshold to the voltage difference module 140, which converts the force difference to an equivalent voltage difference. For example, the voltage difference module 140 may use one or more equations derived from the equivalent circuits 200A-200D to convert the force difference into an equivalent voltage difference.

The voltage difference module 140 outputs the equivalent voltage difference to the limiter 145, which is configured to output a voltage to the power amplifier 115. The voltage output by the limiter 145 is limited by the amount indicated by the equivalent voltage difference output by the voltage difference module 140. As an example, if the voltage difference module outputs a difference of 3 decibels (dB) to the limiter 145 and the voltage input is −10 dB, the limiter 145 outputs a voltage of −13 dB to the power amplifier 115. If the equivalent voltage difference output by the voltage difference module 140 is less than a working threshold of the limiter 145, the limiter 145 bypasses the voltage signal to the power amplifier 115. Accordingly, when the equivalent voltage difference output by the voltage difference module 140 to the limiter 145 indicates that the predicted amount of force exerted by the driver 110 exceeds the force threshold, the limiter 145 limits, or reduces, the power input of the power amplifier 115 such that the force exerted by the driver 110 does not exceed the force threshold thereby preventing mechanical failure of the driver 110.

In some instances, the limiter 145 is implemented as a multiband limiter that smooths audio compression without causing a sudden loudness in the audible signal produced by driver 110. In some instances, the limiter 145 is implemented as a time domain limiter, such as a single band limiter, that is capable of handling sudden surges in the audio signal. In some instances, the limiter 145 includes both a multiband limiter that operates in the frequency domain and a time domain limiter that is operated on top of the multiband limiter.

FIG. 3 provides a method 300 of force-controlled protection of a loudspeaker. Some of the steps included in method 300 are performed by one or more of the electronic processing modules, such as the force prediction module 130 and the limiter 145, included in the controller 120. However, it should be understood that in some instances, the steps of method 300 described as being performed by one or more electronic processing modules of the controller 120 may also be described as generally being performed by the controller 120.

At step 305, the controller 120 receives an audio signal from the audio source 105 (step 305). At step 310, the controller 120 predicts the amount of force exerted by the driver 110 based on a voltage of the audio signal received at step 305 (step 310). In some instances, as described above, the controller 120 predicts the amount of force exerted by the driver 110 using Equation 1. In such instances, the controller 120 uses Equation 1 to predict the amount of force exerted by the driver 110 based on the voltage of the audio signal received from the audio source 105 and the linear parameters of the driver 110.

At step 315, the controller 120 determines whether the predicted amount of force exerted by the driver 110 exceeds a force threshold stored in the memory 125 (step 315). When the predicted amount of force exceeds the force threshold stored in the memory 125, the controller 120 limits the power output of the power amplifier 115, thereby reducing the amount of force exerted by the driver 110 (step 320). For example, the limiter 145 included in and/or coupled to the controller 120 limits the voltage amount provided to the power amplifier 115 to the driver 110, thereby limiting the amount of force exerted by the driver 110, when the predicted amount of force exceeds the force threshold. However, if the controller 120 determines that the predicted amount of force exerted by the driver 110 is less than the force threshold, the controller 120 does not limit the voltage amount provided to the power amplifier 115 (step 325).

The system 100 and the method 300 described above provide open-loop force-controlled protection systems and methods for protecting a loudspeaker from mechanical failure, as the controller 120 does not control operation of the power amplifier 115 and/or the driver 110 based on system feedback. For example, the controller 120 does not receive any measured current and/or power feedback, such as current feedback, from the power amplifier 115 that indicative of an actual amount of force exerted by the driver 110. Rather, the controller 120 controls operation of the power amplifier 115 and/or the driver 110 based on the predicted amount of force exerted by the driver 110 and the values of the linear parameters stored in the memory. However, in some instances, the linear parameters of the driver 110 may be altered by environmental conditions, such as changes in temperature near the driver 110, thereby affecting the accuracy of the force prediction module 130 included in the controller 120. Thus, in some instances, it would be advantageous to modify the predicted amount of force exerted by the driver 110 by current and/or power feedback data indicative of an actual amount of force exerted by the driver 110.

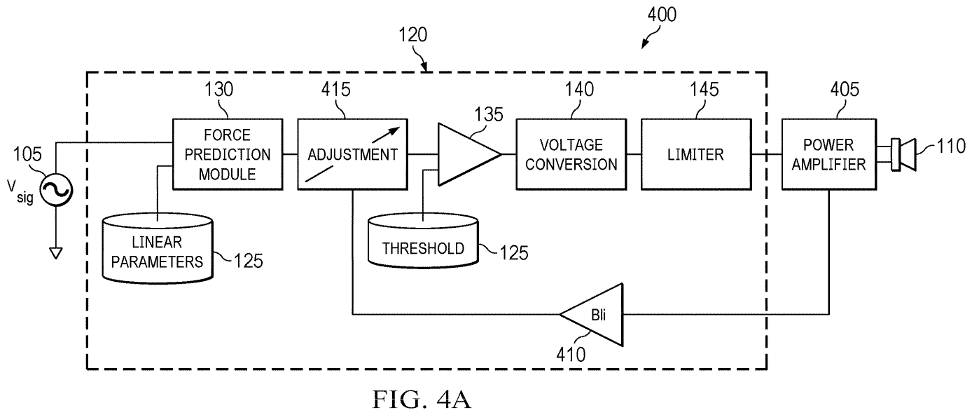

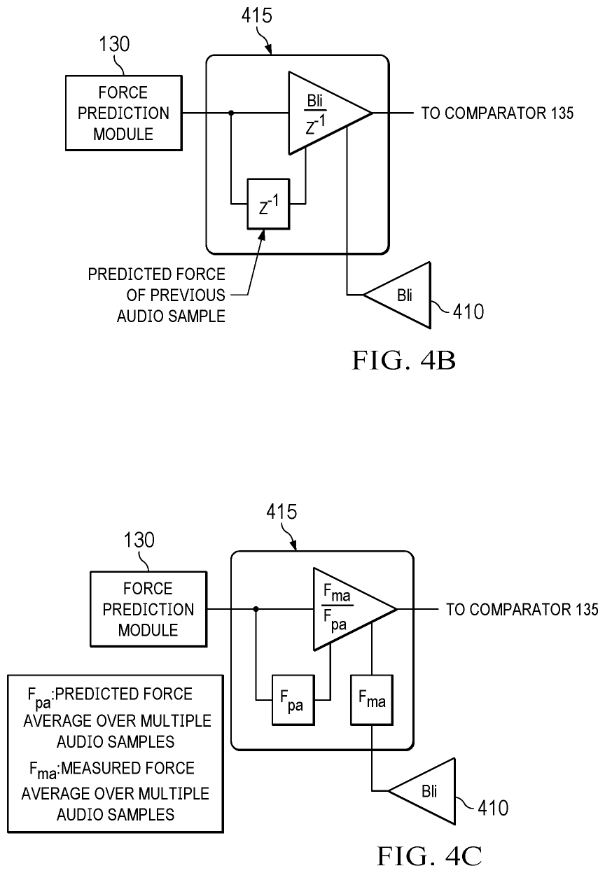

FIG. 4A depicts an example block diagram of a closed-loop force-controlled protection system 400 for a loudspeaker in which operation of the speaker driver is controlled based in part on current and/or power feedback data indicative of an amount of force exerted by the speaker driver. As shown, the system 400 includes many of the same components, such as the audio source 105, the driver 110, the controller 120, and the electronic processing modules included in and/or otherwise connected to the controller 120, that are included in the system 100 described herein and shown in FIG. 1. However, the system 400 further includes additional components that are used to modify the predicted amount of force exerted by the driver 110 based current and/or power feedback data indicative of the amount of force exerted by the driver 110.

For example, the system 400 further includes a smart power amplifier 405. Similar to the power amplifier 115 included in the system 100, the smart power amplifier 405 is configured to amplify the relatively low-power audio signal input by the audio source 105 to a level that is high enough for playback by the driver 110. However, the smart power amplifier 405 is further configured to provide current feedback to the controller 120. The current feedback is indicative of an amount of current consumed by the driver 110, and thus, is indicative of an amount of force exerted by the driver 110. In some instances, the smart power amplifier 405 provides additional feedback, such as power and/or voltage feedback, to the controller 120.

As further shown in FIG. 4A, the controller 120 additionally includes a force conversion module 410 and a force adjustment module 415. The force conversion module 410 converts the current feedback data received from the smart power amplifier 405 into an actual amount of force exerted by the driver 110. For example, the force conversion module 410 uses Equation 19 below to convert the amount of current consumed by the driver 110 into an actual amount of force exerted by the driver 110. As expressed by Equation 19, the actual amount of force exerted by the driver 110 is equal to the product of the amount of current (i) consumed by the driver 110 and the force factor Bl of the driver 110, which is a linear parameter of the driver 110 that is stored in the memory 125. The force conversion module 410 outputs the actual amount of force exerted by the driver 110 to the force adjustment module 415.

$$F = Bli \qquad [ Equation 19 ]$$

The force adjustment module 415 receives, from the force prediction module 130, the predicted amount of force exerted by the driver 110 for a current audio sample(s) that is to be output via the driver 110. The force adjustment module 415 also receives, from the force conversion module 410, the actual amount of force exerted by the driver 110 while the driver 110 was outputting a previous audio sample (or an average actual amount of force exerted by the driver 110 for a plurality of previous audio samples).

In one example, a modified force value output by the force adjustment module 415 to the comparator 135 is the average of the predicted amount of force exerted by the driver 110 for the current audio sample and the actual amount of force exerted by the driver 110 for the previous audio sample (or an average actual amount of force exerted by the driver 110 for a plurality of previous audio samples). In another example, the modified force value output by the force adjustment module 415 is simply equal to the actual amount of force exerted by the driver 110, for example, when the difference between the predicted amount of force exerted by the driver 110 and the actual amount of force exerted by the driver 110 exceeds a difference threshold. In another example, the modified force value output by the force adjustment module 415 is simply equal to the predicted amount of force exerted by the driver 110, for example, when the difference between the predicted amount of force exerted by the driver 110 and the actual amount of force exerted by the driver 110 is less than a difference threshold.

In some instances, the force adjustment module 415 utilizes and/or adjusts a dynamic factor that is used to adjust the predicted amount of force exerted by the driver 110 that is received from the force prediction module 130 based on a comparison between the predicted amount of force exerted by the driver 110 and the actual amount of force exerted by the driver 110. For example, the force adjustment module 415 determines the dynamic factor using Equation 20 below that divides the actual force exerted by the driver 110 (Bli) (as received from the force conversion module 410) by the predicted amount of force exerted by the driver 110 (Fₚ) (as received from the force prediction module 130).

$$Dynamic Factor = \frac{Bli}{Fp} \qquad [ Equation 20 ]$$

FIGS. 4B and 4C show example block diagrams of the force adjustment module 415 according to two respective example implementations. In FIG. 4B, the force adjustment module 415 utilizes an actual force value for a single previous audio sample and a predicted force value for the single previous audio sample (Z⁻¹) to determine the dynamic factor that is multiplied with one or more future predicted force values. On the other hand, in FIG. 4C, the force adjustment module 415 utilizes actual force values for multiple previous audio samples (e.g., an average actual/measured force value for a plurality of previous audio samples (Fₘₐ)) and predicted force values for the multiple previous audio samples (e.g., an average predicted force value for a plurality of previous audio samples (Fₚₐ)) to determine the dynamic factor that is multiplied with one or more future predicted force values. The amounts of audio samples included in the plurality of previous audio samples that are used to determine the measured force average over multiple audio samples (Fₘₐ) and the predicted force average over the multiple audio samples (Fₚₐ) may be any amount of audio samples chosen by a user (e.g., average force of 10 audio samples, 25 audio samples, 128 audio samples, 256 audio samples, 1024 audio samples, or the like). As is evident from FIGS. 4B and 4C and the above explanation, the force adjustment module 415 may dynamically adjust, based on actual force value(s) from the force conversion module 410, the dynamic factor that is multiplied with the predicted force value from the force prediction module 130 to generate the modified force value provided by the force adjustment module 415 to the comparator 135 more accurately in some situations. Thus, in some instances, the force adjustment module 415 scales, or normalizes, the predicted amount of force exerted by the driver 110 for future force predictions based on the actual amount of force exerted by the driver 110 and outputs the modified force value that is the scaled version of the predicted amount of force exerted by the driver 110. In some instances, the dynamic factor is adjusted to attempt to make the predicted amount of force determined by the force prediction module 130 approximately equivalent to the actual amount of force exerted by the driver 110.

The force adjustment module 415 outputs the modified force value to the comparator 135, which compares the modified force value to a force threshold stored in the memory 125. For example, the comparator 135 determines a difference between the modified force value and a force threshold stored in memory 125. The comparator 135 outputs the difference between the modified force value and the force threshold to the voltage difference module 140, which converts the force difference to an equivalent voltage difference. For example, the voltage difference module 140 may use one or more equations derived from the equivalent circuits 200A-200C to convert the force difference into an equivalent voltage difference.

The voltage difference module 140 outputs the equivalent voltage difference to the limiter 145, which, as described above, is configured to output a voltage to the power amplifier 115. The voltage output by the limiter 145 is limited by the amount indicated by the equivalent voltage difference output by the voltage difference module 140. If the equivalent voltage difference output by the voltage difference module 140 is less that a working threshold of the limiter 145, the limiter 145 bypasses the voltage signal to the power amplifier 115. Accordingly, when the equivalent voltage difference output by the voltage difference module 140 to the limiter 145 indicates that the predicted amount of force exerted by the driver 110 exceeds the force threshold, the limiter 145 limits, or reduces, the power input of the power amplifier 115 such that the force exerted by the driver 110 does not exceed the force threshold thereby preventing mechanical failure of the driver 110.

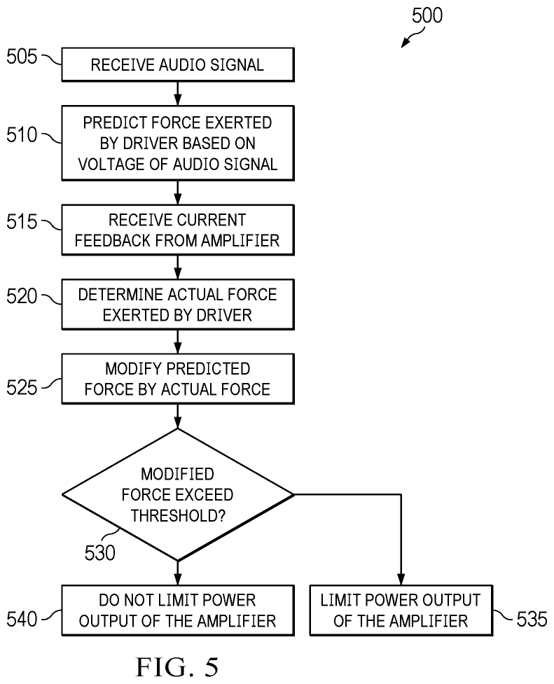

FIG. 5 provides a method 500 of force-controlled protection of a loudspeaker. Some of the steps included in method 500 are performed by one or more of the electronic processing modules, such as the force prediction module 130, the limiter 145, the force conversion module 410, and the force adjustment module 415, included in the controller 120. However, it should be understood that in some instances, the steps of method 500 described as being performed by one or more electronic processing modules of the controller 120 may also be described as generally being performed by the controller 120.

At step 505, the controller 120 receives an audio signal from the audio source 105 (step 505). At step 510, the controller 120 predicts the amount of force exerted by the driver 110 based on a voltage of the audio signal received at step 505 (step 510). In some instances, as described above, the controller 120 predicts the amount of force exerted by the driver 110 using Equation 1. In such instances, the controller 120 uses Equation 1 to predict the amount of force exerted by the driver 110 based on the voltage of the audio signal received from the audio source 105 and the linear parameters of the driver 110.

At step 515, the controller receives current feedback data indicative of an actual amount of force exerted by the driver 110 from the smart power amplifier 405 (step 515). At step 520, the controller 120 determines the actual amount of force exerted by the driver 110 based on the current feedback data (step 520). For example, the force conversion module 410 uses Equation 11 to determine the actual amount of force exerted by the driver 110 based on the current feedback data and the force factor Bl of the driver 110. At step 525, the controller 120 modifies the predicted amount of force exerted by the driver 110 by the actual amount of force exerted by the driver 110 (step 525). For example, the force adjustment module 415 modifies the predicted amount of force exerted by the driver 110 by the actual amount of force exerted by the driver 110 using one or more of the methods described above.

At step 530, the controller 120 determines whether the modified force value exceeds a force threshold stored in the memory 125 (step 530). When the modified force value exceeds the force threshold stored in the memory 125, the controller 120 limits the power output of the power amplifier 115, thereby reducing the amount of force exerted by the driver 110 (step 535). For example, the limiter 145 included in and/or coupled to the controller 120 limits the voltage amount provided to the power amplifier 115 to the driver 110, thereby limiting the amount of force exerted by the driver 110, when the modified force exceeds the force threshold. However, if the controller 120 determines that the modified force value exerted by the driver 110 is less than the force threshold, the controller 120 does not limit the voltage amount provided to the power amplifier 115 (step 540).

When compared to existing loudspeaker protection systems and methods that include controlling the loudspeaker based on excursion of the speaker driver, the force-controlled protection systems and methods described herein are more accurate. For example, the difference between a predicted amount of force exerted by the driver 110, for example a predicted amount of force determined using the methods described herein, and an actual measured amount of force exerted by the driver 110 is much smaller than the difference between a predicted amount of excursion experienced by a speaker driver, for example a predicted amount of excursion using known methods, and an actual measured amount of excursion experienced by a speaker driver. Therefore, controlling operation of a speaker driver based on an amount of force that is predicted using the methods and/or equations described herein is a more accurate than controlling operation of a speaker driver based on a predicted amount of excursion with respect to measured operating parameters of the speaker driver.

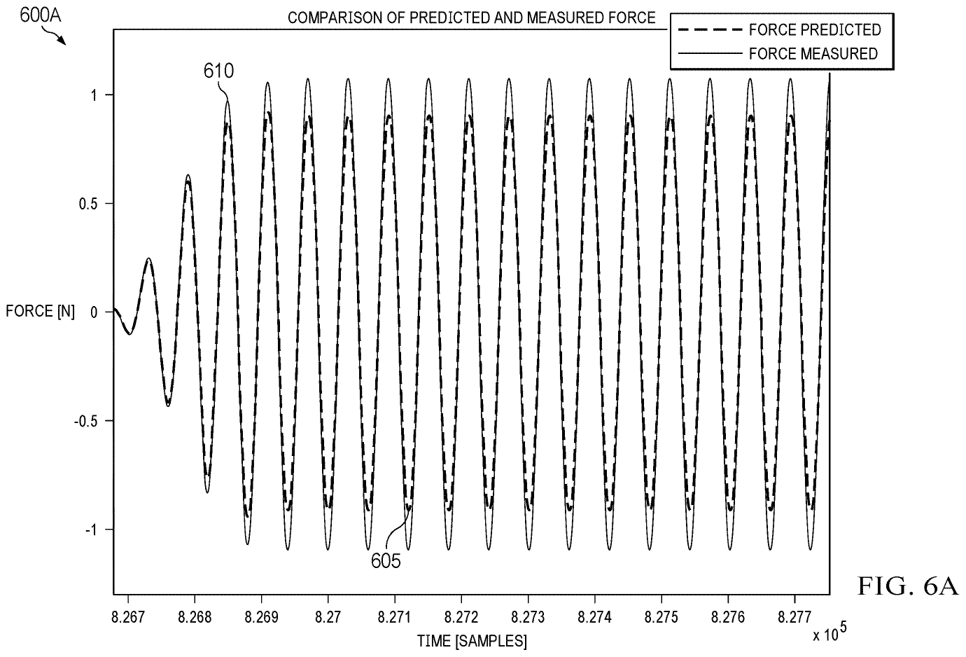

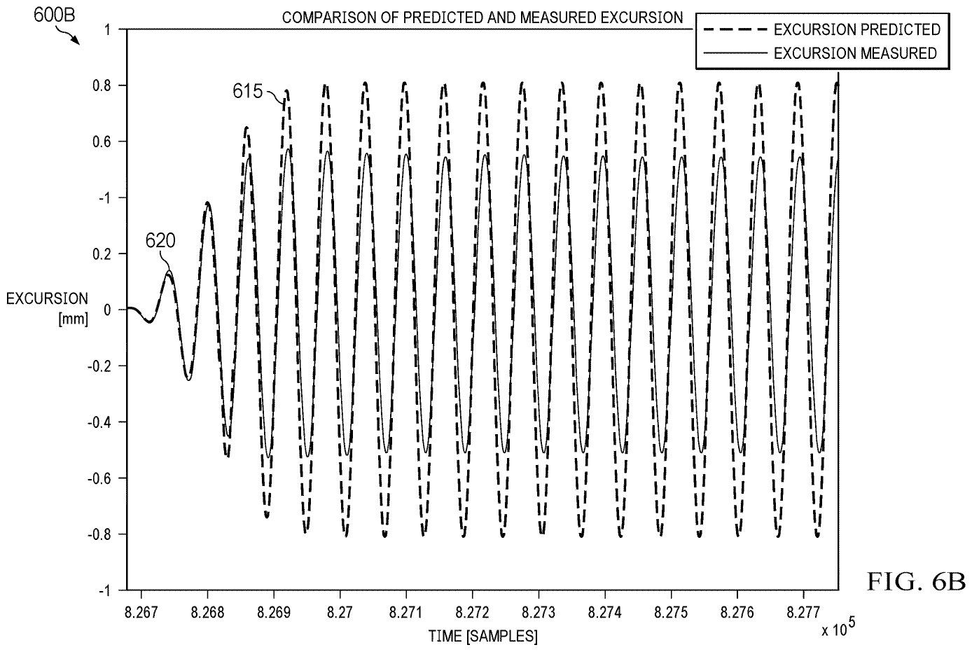

FIG. 6A is an example graph 600A that includes a first curve 605 indicative of the predicted amount of force exerted by the driver 110 operating at resonant frequency and a second curve 610 indicative of the actual measured amount of force exerted by the driver 110 operating at resonant frequency. FIG. 6B is an example graph 600B that includes a third curve 615 indicative of the predicted amount of excursion experience by the driver 110 operating at resonant frequency and a fourth curve 620 indicative of the actual measured amount of excursion experienced by the driver 110 operating at resonant frequency. As shown, the peak amplitude of the first curve 605 is approximately 0.8 N and the peak amplitude of the second curve 610 is approximately 1.0 N. Thus, the percentage difference between the peak amplitudes of the first and second curves 605, 610 is approximately 22%. In contrast, the percentage difference between the peak amplitudes of the third and fourth curves 615, 620 is approximately 33%, as the peak amplitude of the third curve 615 is approximately 0.8 mm and the peak amplitude of the fourth curve 620 is approximately 0.575 mm. Therefore, according to the example graphs 600A, 600B, the force-controlled speaker protection method described herein is approximately 11% more accurate than existing excursion-controlled speaker protection methods.

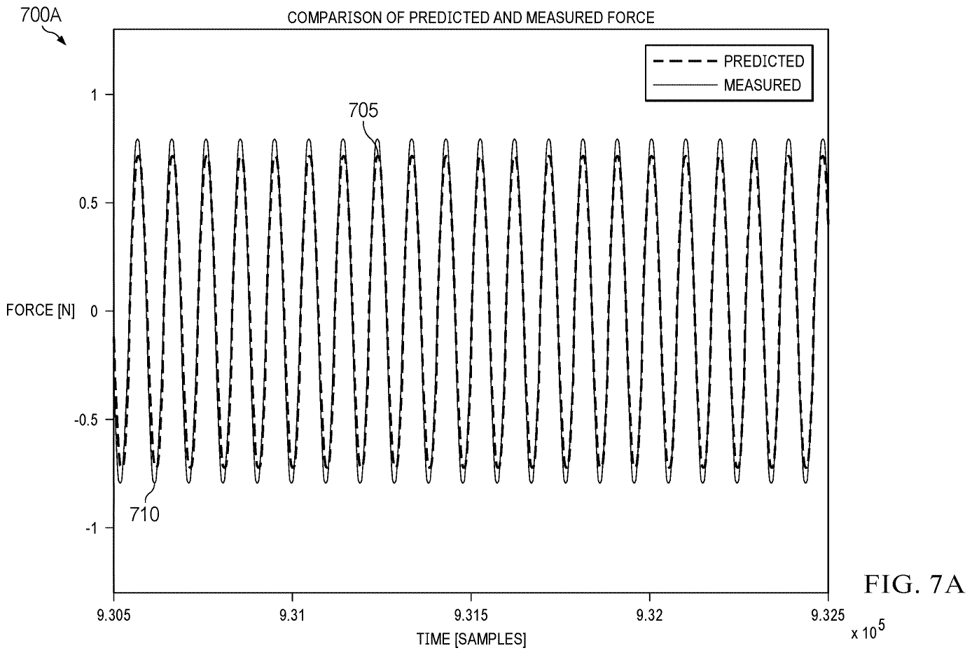

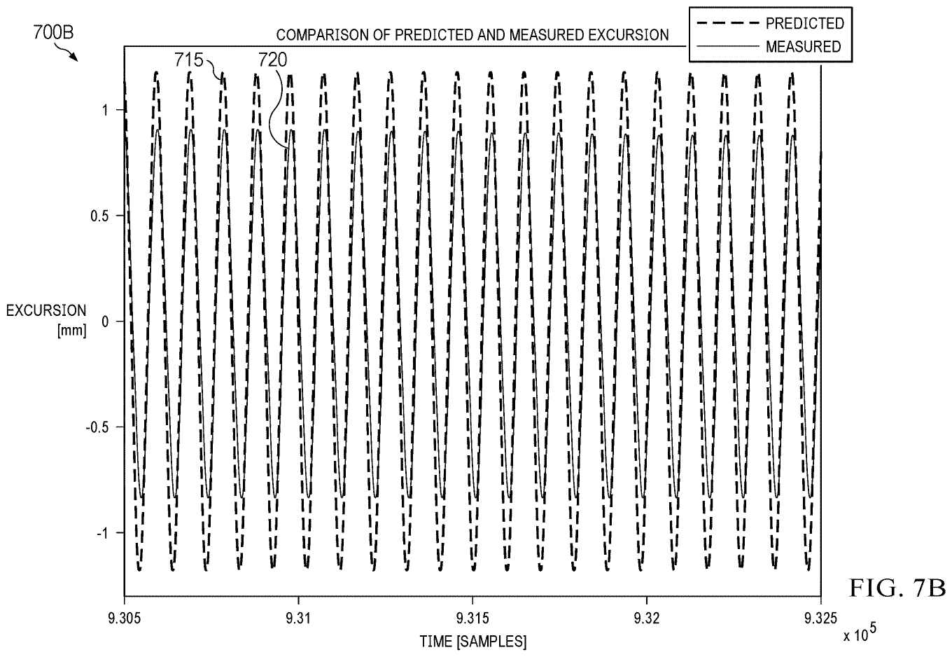

FIG. 7A is another example graph 700A that includes a first curve 705 indicative of the predicted amount of force exerted by the driver 110 operating at resonant frequency and a second curve 710 indicative of the actual measured amount of force exerted by the driver 110 operating at resonant frequency. FIG. 7B is another example graph 700B that includes a third curve 715 indicative of the predicted amount of excursion experience by the driver 110 operating at resonant frequency and a fourth curve 720 indicative of the actual measured amount of excursion experienced by the driver 110 operating at resonant frequency. As shown, the peak amplitude of the first curve 705 is approximately 0.7 N and the peak amplitude of the second curve 710 is approximately 0.75 N. Thus, the percentage difference between the peak amplitudes of the first and second curves 705, 710 is approximately 7%. In contrast, the percentage difference between the peak amplitudes of the third and fourth curves 715, 720 is approximately 34%, as the peak amplitude of the third curve 715 is approximately 1.2 mm and the peak amplitude of the fourth curve 720 is approximately 0.85 mm. Therefore, according to the example graphs 700A, 700B, the force-controlled speaker protection method described herein is approximately 27% more accurate than existing excursion-controlled speaker protection methods.

### Effects

Systems, methods, and devices in accordance with the present disclosure may take any one or more of the following configurations.
(1) A force-controlled loudspeaker protection system that includes a driver, an audio source that outputs an audio signal for playback by the driver, a power amplifier that provides power to the driver for playing back the audio signal, and a controller including an electronic processor. The controller is configured to receive the audio signal from the audio source, predict an amount of force exerted by the driver based on a voltage level of the audio signal, determine whether the predicted amount of force exceeds a threshold, and limit an amount of voltage provided to the power amplifier when the predicted amount of force exceeds the threshold.
(2) The force-controlled loudspeaker protection system according to (1), wherein the controller is further configured to predict the amount of force exerted by the driver based on a plurality of linear parameters associated with the driver.
(3) The force-controlled loudspeaker protection system according to any one of (1)-(2), wherein the controller is further configured to predict the amount of force exerted by the driver based on a velocity of a diaphragm of the driver, an acceleration of the diaphragm of the driver, and an excursion of the diaphragm of the driver.
(4) The force-controlled loudspeaker protection system according to any one of (1)-(3), wherein the force threshold is indicative of an amount of force that results in mechanical failure of the driver.
(5) The force-controlled loudspeaker protection system according to any one of (1)-(4), wherein the controller is further configured to receive current feedback from the power amplifier; and wherein the current feedback is indicative of an amount of current consumed by the driver.
(6) The force-controlled loudspeaker protection system according to (5), wherein the controller is further configured to determine an actual amount of force exerted by the driver based on the current feedback.
(7) The force-controlled loudspeaker protection system according to (6), wherein the controller is further configured to modify the predicted amount of force exerted by the driver by the actual amount of force exerted by the driver; and limit the amount of voltage provided to the power amplifier when a modified predicted amount of force exceeds the threshold.
(8) The force-controlled loudspeaker protection system according to (7), wherein the modified predicted amount of force is an average of the predicted amount of force exerted by the driver and the actual amount of force exerted by the driver.
(9) The force-controlled loudspeaker protection system according to any one of (1) to (8), wherein the controller includes a multi-band limiter that is configured to limit the amount of voltage provided to the power amplifier.
(10) The force-controlled loudspeaker protection system according to any one of (1) to (9), wherein the power amplifier is a current-controlled power amplifier.
(11) A method for force-controlled protection of a loudspeaker. The method includes receiving, from an audio source, an audio signal for playback by a loudspeaker driver, predicting, by a controller including an electronic processor, an amount of force exerted by the driver based on a voltage of the audio signal, determining, by the controller, whether the predicted amount of forces exceeds a force threshold, and limiting, by the controller, an amount of voltage provided to a power amplifier when the predicted amount of force exceeds the force threshold.
(12) The method according to (11), further comprising predicting, by the controller, the amount of force exerted by the driver based on a plurality of linear parameters associated with the driver.
(13) The method according to any one of (11) to (12), further comprising predicting, by the controller, the amount of force exerted by the driver based on a velocity of a diaphragm of the driver, an acceleration of the diaphragm of the driver, and an excursion of the diaphragm of the driver.
(14) The method according to any one of (11) to (13), wherein the force threshold is indicative of an amount of force that results in mechanical failure of the driver.
(15) The method according to any one of (11) to (14), further comprising receiving, by the controller, current feedback from the power amplifier; and wherein the current feedback is indicative of an amount of current consumed by the driver.
(16) The method according to (15), further comprising determining an actual amount of force exerted by the driver based on the current feedback.
(17) The method according to (16), further comprising modifying, by the controller, the predicted amount of force exerted by the driver by the actual amount of force exerted by the driver; and limiting, by the controller, the amount of voltage provided to the power amplifier when a modified predicted amount of force exceeds the threshold.
(18) The method according to (17), wherein the modified predicted amount of force is an average of the predicted amount of force exerted by the driver and the actual amount of force exerted by the driver.
(19) The method according to any one of (11)-(18), wherein the power amplifier is a current-controlled power amplifier.
(20) A non-transitory computer-readable medium storing instructions that, when executed by an electronic processor, cause the electronic processor to perform operations according to any one of (11) to (19).

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments incorporate more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

1. A force-controlled protection system for a loudspeaker driver, the system comprising:
the loudspeaker driver;
an audio source that outputs an audio signal for playback by the loudspeaker driver;
a power amplifier that provides power to the loudspeaker driver for playing back the audio signal; and
a controller including an electronic processor, the controller configured to:
receive the audio signal from the audio source;
predict an amount of force exerted by the loudspeaker driver based on a voltage level of the audio signal;
determine whether the predicted amount of force exceeds a threshold; and
limit an amount of voltage provided to the power amplifier when the predicted amount of force exceeds the threshold.

2. The force-controlled protection system according to claim 1, wherein the controller is further
configured to predict the amount of force exerted by the loudspeaker driver based on a plurality of linear parameters associated with the loudspeaker driver.

3. The force-controlled protection system according to claim 1, wherein the controller is further
configured to predict the amount of force exerted by the loudspeaker driver based on a velocity of a diaphragm of the loudspeaker driver, an acceleration of the diaphragm of the loudspeaker driver, and an excursion of the diaphragm of the loudspeaker driver.

4. The force-controlled protection system according to claim 1, wherein the force threshold is indicative of an amount of force that results in mechanical failure of the loudspeaker driver.

5. The force-controlled protection system according to claim 1, wherein the controller is further configured to receive current feedback from the power amplifier; and
wherein the current feedback is indicative of an amount of current consumed by the loudspeaker driver.

6. The force-controlled protection system according to claim 5, wherein the controller is further configured to determine an actual amount of force exerted by the loudspeaker driver based on the current feedback.

7. The force-controlled protection system according to claim 6, wherein the controller is further configured to:
modify the predicted amount of force exerted by the loudspeaker driver by the actual amount of force exerted by the loudspeaker driver; and
limit the amount of voltage provided to the power amplifier when a modified predicted amount of force exceeds the threshold.

8. The force-controlled protection system according to claim 7, wherein the modified predicted amount of force is an average of the predicted amount of force exerted by the loudspeaker driver and the actual amount of force exerted by the loudspeaker driver.

9. The force-controlled protection system according to claim 1, wherein the controller includes a multi-band limiter that is configured to limit the amount of voltage provided to the power amplifier.

10. The force-controlled protection system according to claim 1, wherein the power amplifier is a current-controlled power amplifier.

11. A method for force-controlled protection of a loudspeaker driver, the method comprising:
receiving, from an audio source, an audio signal for playback by the loudspeaker driver;
predicting, by a controller including an electronic processor, an amount of force exerted by the loudspeaker driver based on a voltage of the audio signal;
determining, by the controller, whether the predicted amount of force exceeds a force threshold; and
limiting, by the controller, an amount of voltage provided to a power amplifier when the predicted amount of force exceeds the force threshold.

12. The method according to claim 11, further comprising predicting, by the controller, the amount of force exerted by the loudspeaker driver based on a plurality of linear parameters associated with the loudspeaker driver.

13. The method according to claim 11, further comprising predicting, by the controller, the amount of force exerted by the loudspeaker driver based on a velocity of a diaphragm of the loudspeaker driver, an acceleration of the diaphragm of the loudspeaker driver, and an excursion of the diaphragm of the loudspeaker driver.

14. The method according to claim 11, wherein the force threshold is indicative of an amount of force that results in mechanical failure of the loudspeaker driver.

15. The method according to claim 11, further comprising receiving, by the controller, current feedback from the power amplifier;
and wherein the current feedback is indicative of an amount of current consumed by the loudspeaker driver.

16. The method according to claim 15, further comprising
determining an actual amount of force exerted by the loudspeaker driver based on the current feedback.

17. The method according to claim 16, further comprising
modifying, by the controller, the predicted amount of force exerted by the loudspeaker driver by the actual amount of force exerted by the loudspeaker driver; and limiting, by the controller, the amount of voltage provided to the power amplifier when a modified predicted amount of force exceeds the threshold.

18. The method according to claim 17, wherein the modified predicted amount of force is an average of the predicted amount of force exerted by the loudspeaker driver and the actual amount of force exerted by the loudspeaker driver.

19. The method according to claim 11, wherein the power amplifier is a current-controlled power amplifier.

20. A non-transitory computer-readable medium storing instructions that, when executed by an electronic processor, cause the electronic processor to perform operations comprising the method of claim 11.
